(19) United States
(12) Patent Application Publication
(10) Pub. No.: US 2003/0112652 A1
(43) Pub. Date: Jun. 19, 2003

(54) Semiconductor integrated circuit

(75) Inventors: Shigeru Shimada, Nishitokyo (JP); Kazumasa Yanagisawa, Kokubunji (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/289,254

(22) Filed: Nov. 7, 2002

(30) Foreign Application Priority Data
Dec. 17, 2001 (JP) 2001-382553

(51) Int. Cl. G11C 11/00

(52) U.S. Cl. 365/154

(57) ABSTRACT

On the first digital circuit, the circuits which must be operated even under the waiting condition such as an SRAM which is required to hold control data or the like even during the waiting condition of a semiconductor integrated circuit and a timer circuit for recovery from the waiting condition and for the waiting operation are formed. A gate insulation film of the MOS transistor forming the first digital circuit is formed to be thicker than that of the MOS transistor of the second digital circuit in which the circuits which are not operated during the waiting condition are formed. Accordingly, the sub-threshold leak current of the first digital circuit to be operated even during the waiting condition and the tunnel leak current of the gate electrode can be reduced. Moreover, when the semiconductor integrated circuit of the present invention is applied to a battery power supply system, the operation life of a battery can be extended.

### BACKGROUND OF THE INVENTION

The present invention relates to a technique to implement low power consumption of a semiconductor integrated circuit, and more specifically to a technique which may be effectively adapted to low power consumption in the waiting condition of a so-called system LSI under the system-on-chip mode loading, for example, logic circuit and memory.

In a semiconductor integrated circuit, a threshold voltage of an insulated gate type field effect transistor (a transistor of this type is expressed in general as MOS (Metal Oxide Semiconductor, and therefore this expression is also used in the present invention) tends to be lowered in response to the requirements for further scale-down in size of elements and high speed operations thereof.

In the case of setting the threshold voltage of a MOS transistor to a small value to enable sufficient circuit operations under a comparatively lower power supply voltage corresponding to a battery voltage, it is impossible to perfectly turn OFF the MOS transistor because of the sub-threshold characteristic of the MOS transistor. Namely, a non-negligible sub-threshold leak current is generated. Moreover, when thickness of gate insulation film (gate film thickness) of the MOS transistor is reduced, a tunnel leak current flows into the gate insulation film. The leak current of the gate insulation film becomes a leak current between the gate electrode and source/drain and substrate. These sub-threshold leak current and tunnel leak current maybe inevitable currents from the viewpoint of operation characteristics of the circuits but these currents bring about a problem that a power consumption in the waiting condition of the semiconductor integrated circuit increases.

As the references in which attention is paid to the sub-threshold leak current or a tunnel leak current, the International Published Patent Application No. WO97/38444, Japanese Unexamined Patent Publication Nos. 2001-015704, 2000-058675, Hei 11(1999)-297950 and Hei 11(1999)-040775 can be listed.

### SUMMARY OF THE INVENTION

In the system LSI having a large scale logic circuits which is called a system-on-chip, a part of the circuits must be operated continuously even in the waiting condition. The so-called CMOS (Complementary MOS) integrated circuit device is expected to implement the operations of low power consumption with its complementary operations of the P-channel MOS transistor and N-channel MOS transistor as the structural elements and is considered to be suitable to form the system LSI explained above.

The inventors of the present invention has investigated, based on such concept, the technique to lower the power consumption caused by the sub-threshold leak current. For example, in the system LSI for communication such as a mobile phone, the SRAM for holding control data or the like for operation as a terminal and a circuit such as a timer for the recovery operation or waiting condition must always be operated even in the waiting condition of the LSI chip. In this case, when the MOS transistor of the circuit region having the SRAM and timer, etc. is formed of the transistor having a comparatively thin gate oxide film, a sub-threshold leak current flowing into the circuit which must always be operated is no longer negligible. A current of this kind flows to shorten the life-span of a battery in the system which is operated by a battery or the system including a backup battery when the power failure occurs.

In the case where the threshold voltage of a MOS transistor is set to a small value to assure sufficient circuit operation under the power supply voltage lower than 2 volts corresponding to the voltage of unit battery, namely thickness of the gate insulation film (gate film thickness) of the MOS transistor is set to an extremely small value, the tunnel leak current explained above increases depending on such setting. Since attention must be paid to the tunnel leak current on the occasion of forming a MOS transistor having the low threshold voltage, it may be assumed, in the wider sense, to be in the range of the sub-threshold leak current. On the contrary, the sub-threshold leak current substantially not considering the tunnel leak current may be assumed in the narrow sense as a sub-threshold current.

A means which can effectively reduce a tunnel leak current and a sub-threshold leak current has not yet been provided for a part of the circuits of LSI. A sub-threshold leak current in the narrow sense as explained above can be reduced to a certain extent, for example, by increasing the threshold voltage through implantation of impurity ion to a channel forming region of the MOS transistor or by applying a substrate bias to a so-called substrate gate of the MOS transistor. In this case, when a circuit to form a substrate bias voltage is provided, a problem rises here that electrical power is additionally consumed with this circuit. In addition, technical progress in recent years cannot ignore a junction leak current at the PN-junction between the source/drain region of the MOS transistor and the semiconductor region to form the MOS transistor. A junction leak current increases clearly with application of a substrate bias voltage. The tunnel leak current as explained above changes depending on the characteristic of the gate insulation film itself and therefore such tunnel leak current is not reduced with increase of the threshold voltage due to the implantation of impurity ion. Moreover, since application of the substrate bias voltage explained above increases a field of the gate insulation film, it also increases, on the contrary, the tunnel leak current. As a result, it is very difficult to reduce the power consumption.

An object of the present invention is to provide a semiconductor integrated circuit which can reduce the power consumption from the viewpoint of the sub-threshold leak current.

Another object of the present invention is to provide a semiconductor integrated circuit which can be applied to a system operated by a battery as the power supply and can extend the life-span of the battery.

The aforementioned and other objects and novel characteristics of the present invention will become apparent from description of the specification and the accompanying drawings thereof.

Typical inventions disclosed in the present application will be explained below briefly.

Namely, a semiconductor integrated circuit of the present invention is structured by forming, on the same semiconductor substrate, a first digital circuit including a first memory consisting of a peripheral circuit consisting of an external terminal, an interface circuit connected to the external terminal, a memory array, an address decoder related in direct to the memory array, a column selection circuit and a sense amplifier or the like and a second digital circuit including logic circuits. In this case, MOS transistors forming the first digital circuit have comparatively thick gate insulation films, while MOS transistors forming the second digital circuit have comparatively thin gate insulation films.

For the large scale and complicated semiconductor integrated circuit device, it will be preferable that various circuits forming such device are integrated as the units which can be uniquely discriminated or recognized or as the units having individual operating functions. The first memory explained above may be thought as the device in which the memory cell array and its peripheral circuits are formed in the unit aggregation or as a module, in other words, thought to be formed as a memory module. The memory module may include, as an aggregated unit, a buffer such as an address buffer and a control circuit as required in addition to the structure explained above.

A static random access memory (SRAM) may be preferably defined as the first memory forming the first digital circuit because it is required to hold the control data or the like even during the waiting condition of the semiconductor integrated circuit. For the first digital circuit, it is possible to include thereto a circuit such as a timer circuit which is also operated, even during the waiting condition, for setting the recovery from the waiting condition or setting of the waiting condition. As explained above, a comparatively thick gate insulation film is defined for the MOS transistor which forms the first digital circuit. Thereby, the sub-threshold leak current of the first digital circuit to be operated even in the waiting condition and the tunnel leak current of gate electrode may be reduced.

An example for easier understanding will be explained below. Namely, for example, when the MOS transistor forming the first digital circuit has the gate in the thickness of 8 nm, while the MOS transistor forming the second digital circuit has the gate in the thickness of 3 nm, a sub-threshold leak current of the MOS transistor forming the first digital circuit is reduced almost by a degree of three digits from that of the MOS transistor forming the second digital circuit, and a tunnel leak current of the gate electrode is also reduced almost to zero. As explained above, the sub-threshold leak current can be reduced and the tunnel leak current of the gate electrode can also be reduced. Accordingly, a leak current can be lowered to the level to be negligible even when the memory or the like is set to the waiting condition for holding the data. As a result, a life-span of the battery can be extended when the device is applied to the battery power supply system.

The first memory provides an electrical and structural merits because the memory cell array, so-called direct peripheral circuit which is connected in direct to the memory cell array like the address decoder and column selection circuit and the peripheral circuit such as sense amplifier and buffer are all formed of the MOS transistor having a comparatively thick gate. Namely, since the address decoder and column selection circuit, etc. are formed of a comparatively large number of element circuits corresponding to the memory cell array, these circuits are capable of making a comparatively large contribution for reduction of leak current. Moreover, since the first memory can be formed as the memory module with a MOS transistor of the type having a thin gate, the structure of module can be simplified.

In the case where a plurality of kinds of power supply voltages are applied corresponding to the MOS transistors of different thickness, it is desirable that a signal from the circuit which is operated by a comparatively lower power supply voltage, for example, is transferred to the circuit which is operated by a comparatively higher power supply voltage through conversion to a comparatively higher level with an adequate level converting circuit. Even when such level conversion is considered, it is advantageous for the first memory that this memory as a whole is formed as explained above. Namely, in other words, increase of wirings corresponding to a plurality of power supplies and isolation of certain kinds of semiconductor regions which are required for different power supply systems can be avoided.

The MOS transistor forming the first digital circuit may be formed with inclusion of the gate insulation film of the same thickness as that of the MOS transistor forming the interface circuit. In this case, if the gate thickness of the MOS transistor of the first digital circuit is different from that of the MOS transistor of the second digital circuit, a new fabrication process which will be required to form the MOS transistor having different gate thickness is not required actually.

Addition of a new process is required when the operation rate of the first digital circuit is too slow, but it is enough that a gate insulation film which is comparatively thinner than that of the MOS transistor forming the interface circuit is used as the gate insulation film of the MOS transistor forming the first digital circuit.

When the gate insulation film is employed, it is also possible to selectively use the film, for example, the comparatively thick gate insulation film of MOS transistor forming the interface circuit for the first memory and the comparatively thin gate insulation film for the logic circuit such as a timer, etc.

When the gate thickness of the first digital circuit is unified to a kind of value, the operation power source of the first digital circuit may be used as the single power supply.

Moreover, when it is considered that the operation mode in the waiting condition is different in the first digital circuit and the second digital circuit, it is desirable that the operation power source route of the first digital circuit is isolated from the operation power source route of the second digital circuit. Moreover, an exclusive power supply terminal may be employed for the input of the operation power source of the first digital circuit. In this case, power supply under the waiting condition can be controlled easily. For example, a power supply ring laid at the external side of the first digital circuit may also be employed for the operation power source route of the first digital circuit.

### BRIEF DESCRIPTION OF THE DRAWINGS

FIG. 1 is a schematic plan view of the layout of a semiconductor integrated circuit of the present invention.

FIG. 2 is a vertical cross-sectional view illustrating a MOS transistor having a thick gate.

FIG. 3 is a vertical cross-sectional view illustrating a MOS transistor having a thin gate.

FIG. 4 is a diagram illustrating the sub-threshold leak current characteristic of an N-channel MOS transistor having a thick first gate insulation film.

FIG. 5 is a diagram illustrating the sub-threshold leak current characteristic of an N-channel MOS transistor having the thin second gate insulation film.

FIG. 6 is a diagram illustrating a relationship between a tunnel leak current of gate and a gate thickness.

FIG. 7 is a block diagram of an example of SRAM.

FIG. 8 is a circuit diagram illustrating a memory cell MC in the CMOS static latch mode.

FIG. 9 is a diagram illustrating a structure of a power supply ring of a first block.

FIG. 10 is a diagram illustrating a structure of a power supply ring of a second block.

FIG. 11 is a diagram illustrating a structure of a power supply ring of a third block.

FIG. 12 is a diagram illustrating a structure of a power supply ring of a fourth block.

FIG. 13 is a diagram illustrating a signal control unit.

FIG. 14 is a timing chart illustrating the power supply mode in the operating and waiting conditions of the semiconductor integrated circuit.

FIG. 15 is a block diagram illustrating a mobile phone as a data processing system to which the semiconductor integrated circuit of the present invention is applied.

### DETAILED DESCRIPTION OF THE EMBODIMENTS

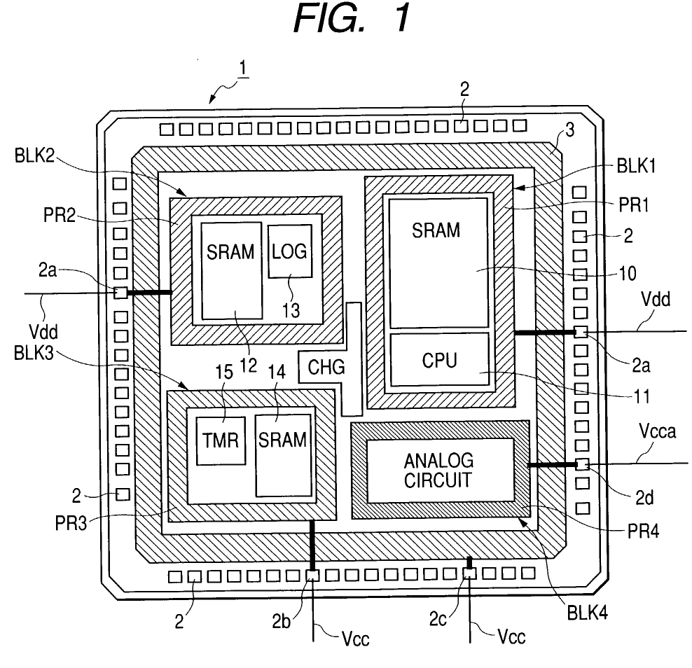

FIG. 1 illustrates an example of a semiconductor integrated circuit of the present invention. The semiconductor integrated circuit 1 is formed as a system LSI and is formed on one semiconductor substrate consisting of a single crystal silicon, for example, with the CMOS semiconductor integrated circuit fabrication technique.

Although not particularly restricted, many bonding pads 2 are formed as external terminals at the circumference of the main surface on a semiconductor substrate and an I/O region 3 is formed as an interface circuit connected to the bonding pads 2 at the internal side of many bonding pads 2. In the I/O region 3, an input/output buffer or the like is formed and a MOS transistor formed in the I/O region 3 includes the first gate insulation film.

At the internal side of the I/O region 3, the third block BLK3 is formed as a first digital circuit, a first block BLK1 and a second block BLK2 as a second digital circuit and moreover an analog block BLK4 and a signal control unit CHG are also formed.

The first block BLK1 includes an SRAM10 as a memory and a CPU 11 as a logic circuit, while the MOS transistor formed in the relevant first block BLK1 includes the second gate insulation film which is thinner than the first gate insulation film. The second block BLK2 includes an SRAM12 as a memory and a custom logic circuit (LOG) as a logic circuit, while the MOS transistor formed in the relevant second block BLK2 includes the second gate insulation film.

The third block BLK3 includes an SRAM14 as a memory and a timer 15 as a logic circuit, while the MOS transistor formed in the relevant third block BLK3 includes a gate insulation film which is thicker than the second gate insulation film, for example, the first gate insulation film.

The analog block BLK4 is formed of a MOS transistor having the first gate insulation film or the second gate insulation film.

In the semiconductor integrated circuit 1, three kinds of operation power sources are used. The first power source Vdd is supplied to the first block BLK1 and second block BLK2. The first power source Vdd is supplied from the external side via an exclusive power supply terminal 2a and when the waiting condition is instructed (waiting condition) to the semiconductor integrated circuit, this power source is cut off, although not particularly restricted, at the external side of the semiconductor integrated circuit. In short, supply of the power source Vdd is cut off.

The second power source Vcc is supplied to the third block BLK3 and I/O region 3. This second power source Vcc is supplied from the external side via the exclusive power supply terminals 2b, 2c and is not cut off even under the waiting condition and supplied continuously from the external side.

The waiting condition means, not particularly restricted, that a semiconductor integrated circuit is placed to the low power consumption condition and this condition is also called a standby condition or a sleeping condition. This waiting condition can be set, for example, when the CPU 11 executes the sleeping instruction or when the standby mode is set by an external signal. Recovery from this waiting condition can be implemented by various control modes such as interruption or recovery with an external signal. At least, the circuit or the like for monitoring the generation of the recovery instruction can be operated depending on such control modes. In the example of FIG. 1, the timer circuit 15 in the third block BLK3 has the recovery monitoring function.

An analog power source Vcca only for analog circuit is supplied to the analog block BLK4 from the exclusive power supply terminal 2d. Under the waiting condition, supply of the power source Vcca is cut off at the external side.

The signal control unit CHG is provided with a level conversion function for the signal required to exchange the signals of different amplitudes among the circuit blocks of different operation power source voltages and an uncertain level compulsory control function for compulsorily setting, for example, to the ground potential Vss of the circuit, the level of an uncertain signal in order to prevent that when the supply of the operation power source is cut off during the waiting condition, the signals outputted from the blocks BLK1, BLK2, BLK4 are supplied to the third block BLK3 while the levels of such signals are uncertain. The power sources of the circuit to implement the level conversion function and uncertain level compulsory control function are defined as Vdd, Vcc and Vcca as explained above. In FIG. 1, the supply routes of these three power sources are omitted. Even in the waiting condition, the operation power source Vcc is supplied to the signal control unit CHG in order to implement uncertain level compulsory control function for the first block BLK3.

The power supply wirings to feed the operation power sources to the blocks BLK1 to BLK4 are given with the inherent power supply rings PR1 to PR4 of the blocks BLK1 to BLK4. The power supply rings PR1 to PR4 have the functions as main power supply lines of the blocks BLK1 to BLK4. Feeding to the corresponding block can be done easily by using the power supply rings PR1 to PR4 and since the power supply rings PR1 to PR4 are isolated individually for each block, the operation power source can also be cut off easily. According to the structure of FIG. 1, it is enough to select at the external side the supply of operation power source to the corresponding power supply terminal. The power supply ring will be explained again later.

In FIG. 1, the SRAM10 in the blocks BLK1, BLK2 are set when the CPU 11 and logic circuit 13 request the SRAM which allows high speed access. Namely, these SRAMs 10, 12 are formed of the MOS transistor having the comparatively thin gate insulation film as explained above and thereby comparatively high speed operation may be implemented depending on the comparatively lower threshold voltage characteristic of the MOS transistor. These SRAMs 10, 12 are also capable of making comparatively small the plain size of the MOS transistors used and therefore is capable of having a large storage capacity per unit area. On the contrary, these SRAMs 10, 12 require a large current under the waiting condition according to the leak current thereof when these SRAMs are operated under the waiting condition because of a comparatively large leak current of the MOS transistors used.

On the other hand, the SRAM 14 in the block BLK3 is formed, as explained above, of the MOS transistor having a comparatively thick gate insulation film and this SRAM is just suitable for the operation under the waiting condition from the viewpoint of a low leak current, although a certain consideration is required for the size such as a plain size of the MOS transistor must be set to a comparatively large value from the operational restriction depending on the comparatively higher threshold voltage characteristic of the MOS transistor and from the viewpoint of fabrication technique of the semiconductor integrated circuit.

When the CPU 10 and logic circuit 13 do not substantially require the high speed SRAM or when the access of only the SRAM such as an SRAM 14 is allowed depending on a comparatively low access frequency, the SRAM such as SRAMs 10, 12 are unnecessary.

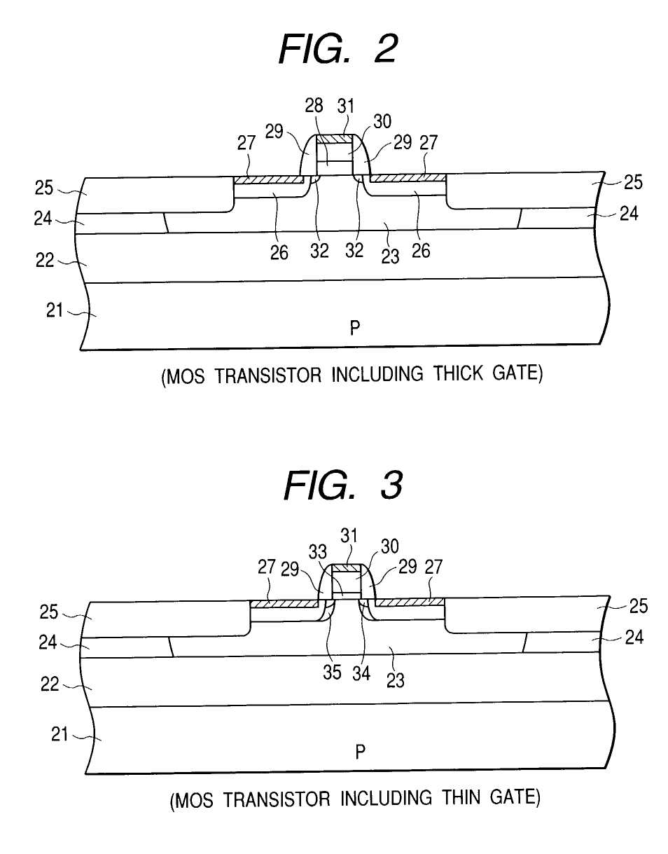

FIG. 2 is a vertical cross-sectional view of the MOS transistor having the thick gate. On the P-type silicon substrate 21, an N-type isolation region 22 is formed and a P-well region 23 and an N-well region 24 are formed thereto. To the P-well region 23, an N-channel MOS transistor is formed and to the N-well region, a P-channel MOS transistor is formed (not illustrated). These MOS transistors are isolated by an element isolating region 25. The N-channel MOS transistor illustrated has a source/drain which is formed of an N-type high concentration impurity region 26. These source and drain are formed of a silicide film 27 to have a low resistance value. At the end portions provided opposed with each other of the source and drain, an N-type low concentration impurity region 32 is formed to form the so-called LDD (Lightly Doped Drain Source) structure. A first gate insulation film 28 consisting of a relatively thick silicon oxide is provided on the P-well region 23 to be used as a channel forming region between the source and drain and a gate electrode 30 consisting of polysilicon is formed thereon. On the gate electrode 30, a conductor film 31 consisting of tungsten silicide is formed to reduce a resistance value. In both sides of the gate electrode, a so-called side wall 29 mainly consisting of the silicon oxide is formed.

FIG. 3 is a vertical cross-sectional view of a MOS transistor having the thin gate. A large difference of the Figure from FIG. 2 is that a second gate insulation film 33 is formed of a relatively thin silicon oxide. Although not particularly restricted, the MOS transistor of FIG. 3 has a short channel, namely a comparatively short distance between the source and drain. In order to control drop of dielectric strength between the source and drain which is recognized as short channel effect, an N-type low concentration impurity region 35 and a P-type low concentration impurity region 35 are formed for the end portions provided opposed with each other of the source and drain with the impurity ion injection which is so-called the “low ion implantation”. The other part is same as that of FIG. 2 and a detailed explanation is omitted here.

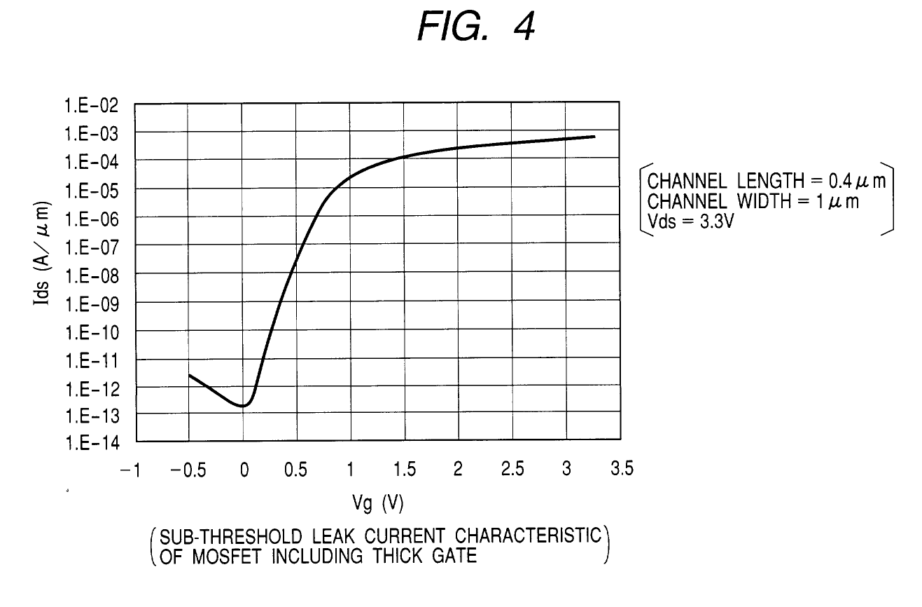

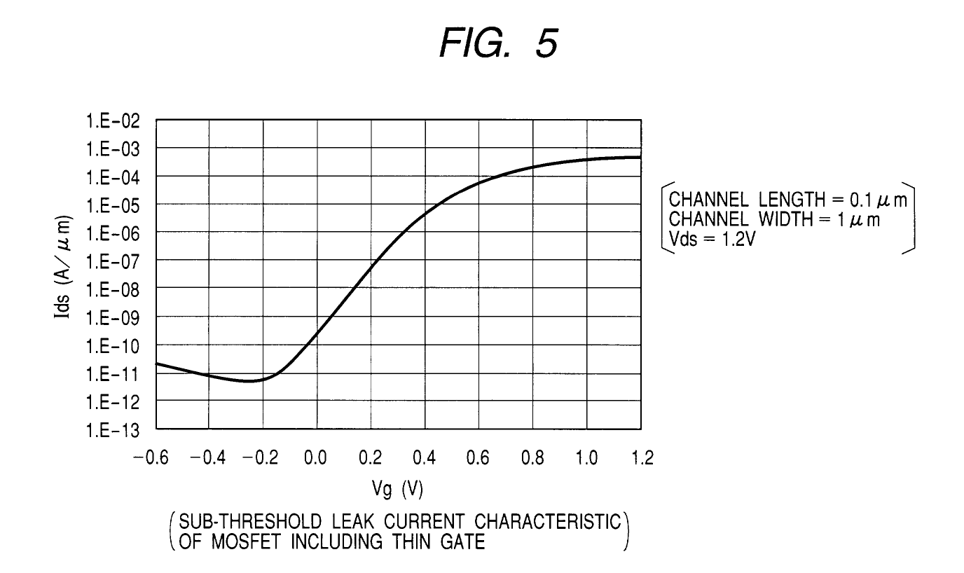

FIG. 4 illustrates a sub-threshold leak current characteristic of unit channel width of an N-channel MOS transistor having the first gate insulation film 28 of the thickness of FIG. 2, for example, the gate insulation film thickness of 8 nm. FIG. 5 illustrates a sub-threshold leak current characteristic of unit channel width of an N-channel MOS transistor having the second gate insulation film 33 of the thickness of FIG. 3, for example, the gate insulation film thickness of 3 nm. In these figures, the vertical axis indicates a drain-to-source current Ids [A], while the horizontal axis indicates a gate voltage [V]. Indication of vertical axis, for example, “E-10” means “10⁻¹⁰”. A drain-to-source voltage for measurement is assumed as 3.3[V], in FIG. 4, corresponding to a comparatively high power source voltage expected for the MOS transistor having the thick gate, while as 1.2[V], in FIG. 5, corresponding to a comparatively low power source voltage expected for the MOS transistor having the thin gate. The data of the P-channel MOS transistor is omitted here but it can be understood that this MOS transistor also has the leak current characteristic which is almost equal to that of the N-channel MOS transistor. As will be apparent from FIG. 4 and FIG. 5, a current which is assumed as a sub-threshold leak current flows also under the gate voltage of 0V or less in the MOS transistor having the gate of any kind of thickness. However, a leak current per channel width at the gate voltage 0[V] of the MOS transistor having the thick gate is about 1.7E-13 [A/μm] and this value is lower by about three digits than the leak current 3.0E-10 [A/μm] of the MOSFET having the thin gate. From the characteristics of the figures, it can be understood that use of the MOS transistor having the thick gate is very effective for reduction of a leak current under the waiting condition of the circuit.

A sub-threshold leak current increases to a large extent when temperature is higher from the point of view of comparatively higher dependence on temperature.

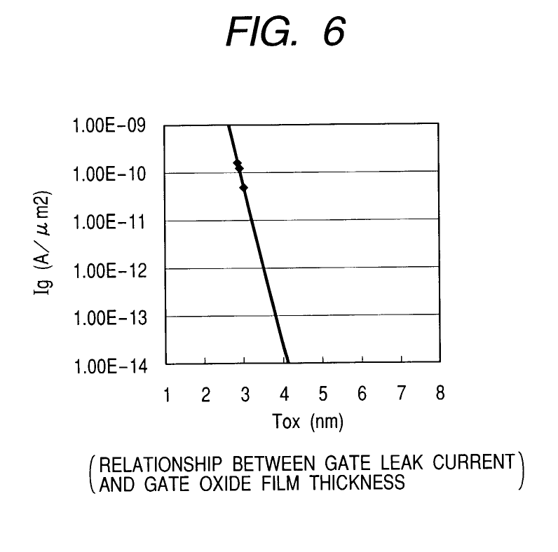

FIG. 6 illustrates a relationship between a tunnel leak current of gate and a gate thickness under the appropriate gate voltage of such as 1.2V. The tunnel leak current is about 1E-10 [A/μm²] in the MOS transistor having the comparatively thin second gate (for example, 3 [μm]) but it becomes to the measurement limit value or less (<1E-16 [A/μm²] in the MOS transistor having the thick first gate (for example, 8 [μm]) and this level can substantially be negligible.

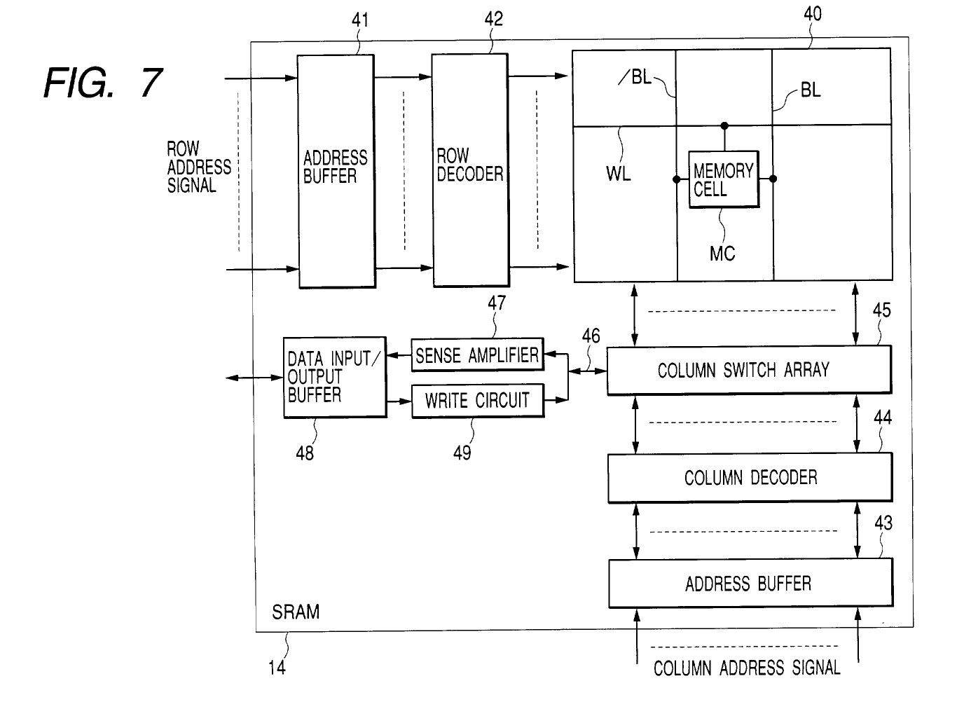

FIG. 7 is a block diagram as an example of an SRAM 14. The SRAM 14 as a whole of the figure forms one memory module.

A memory cell array 40 includes a plurality of static memory cells MC arranged in the shape of a matrix (in FIG. 7, only one memory cell is illustrated typically to simplify the figure). A selection terminal of the memory cell MC is connected to the corresponding word line WL, while a data input/output terminal of the memory cell MC is connected to the corresponding complementary bit lines BL, /BL. A row address buffer 41 receives a low address signal as an input and supplies an output to a row address decoder 42. The row decoder 42 decodes the row address signal to form a word line selection signal. The word line WL is selectively driven with the word line selection signal. A column address buffer 43 receives a column address signal and supplies an output to a column decoder 44. The column decoder 44 decodes the column address signal to form a column selection signal. A column switch array 45 selects the complementary lines BL, /BL corresponding to the column selection signal and connects these lines to a common data line 46. During the read operations, the data read out from the selected memory cells is transferred to the common data line 46 via the complementary bit lines BL, /BL and column switch array 45. A sense amplifier 47 amplifies the read data transferred via the common data line 46 and supplies the amplified output to a data input/output buffer 48. Depending on this operation, the read data is outputted to an external circuit via the data input/output buffer 48. During the write operation, the write data supplied to the data input/output buffer 48 from the external circuit is supplied to the selected memory cell MC via a write circuit 49, common data line 46, column switch array 45 and complementary bit lines BL, /BL. In the SRAM14, all MOS transistors of the memory array 40 and peripheral circuits 41 to 49 have the thick gate insulation films. Therefore, the sub-threshold leak current in the SRAM14 as a whole and the tunnel leak current of the gate can be reduced.

Accordingly, a leak current when a memory module like the SRAM14 is formed of the MOS transistor having the thin gate and a leak current when such memory module is formed of the MOS transistor having the thick gate will further be explained.

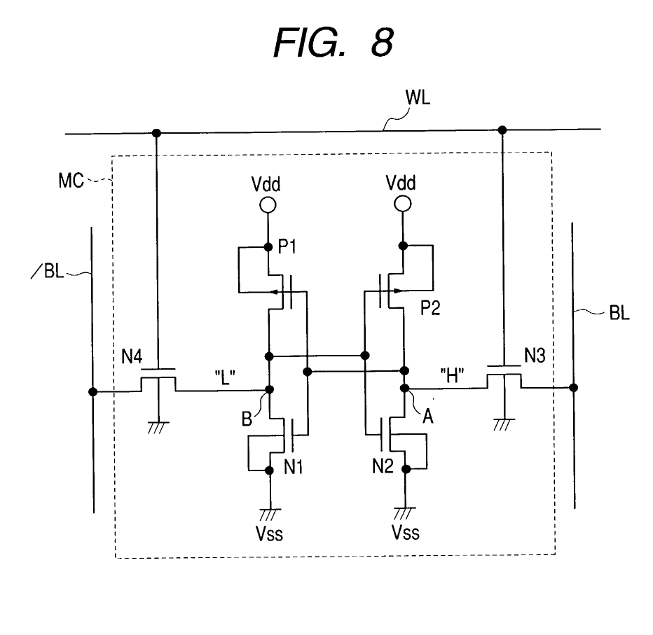

FIG. 8 illustrates a circuit of the memory cell MC of the CMOS static latch mode.

In this figure, it is assumed that potential of the data holding node A (hereinafter, referred only to as point A) in the waiting condition is “H (high level)”, while potential of the data holding node B (point B) is “L (low level)”. In this case, it is also assumed that the transfer data MOS transistors in the memory cell MC, namely the N-channel MOS transistors N3, N4 provided between the data holding nodes A, B and the complementary bit lines BL, /BL are driven to the OFF state with the low level which is the non-selection level of the word line WL.

In this case, the MOS transistors P1 and N2 are driven in the OFF state depending on the levels of the points A and B, but since the power source voltage Vdd is impressed to the drain of these MOS transistors, a sub-threshold leak current flows into these transistors. A sub-threshold leak current also flows to the transfer gate MOS transistor. When the SRAM is formed to maintain the complementary bit lines BL, /BL in the waiting condition to the low level, a leak current route is formed between the high level side node of the nodes A and B and the complementary bit lines BL, /BL via the transfer MOS transistor N3. In the example of potential in FIG. 8, a leak current flows into the transfer gate MOS transistor N3.

Here, when it is assumed that a plurality of MOS transistors generating a leak current during the waiting condition is replaced with an equivalent MOS transistor, a channel width which proportionally gives influence on a leak current of the equivalent MOS transistor can also be assumed to be equal to a sum of the channel widths of the two N-channel MOS transistors N2, N3 in the OFF state and a P-channel MOS transistor P1.

When the memory cell is formed of the MOS transistor having the thin gate, for example, the second gate (for example, 3 [μm]) as a typical example, a sum of the channel width in the equivalent sense of the memory cell like a static memory cell can be set almost to 0.6 [μm].

Although not accurate, a sum of the channel widths of the memory array and a sum of the channel widths of the MOS transistors generating a leak current in the MOS transistors forming the peripheral circuits other than the memory array are considered from the viewpoint of a ratio thereof from the convenience of explanation, such ratio may be thought as about 1:0.2.

(a) For example, when the memory of 512 kbits as a whole is formed of the MOS transistor having the thin second gate insulation film, a sum of the total channel widths of the memory cells generating a leak current during the waiting condition is obtained as 0.6×512×1024 =314573 [[μm] and that of the peripheral circuits is about 20% thereof, namely 62915 [μm].

In this case, a leak current of the memory module as a whole becomes 1.1E-4[A] because a sum of the channel widths of the module as a whole is 377488 [μm] and a leak current when the gate voltage is 0V is 3.0E-10 [A/μm] per unit channel width from FIG. 5.

(b) The peripheral circuit is assumed as a MOS transistor having the thin gate and only the memory cell is replaced with the MOS transistor having the thick gate. In this case, it is required to make wide the channel width from the condition that thick gate is disadvantageous for execution of fine process. Therefore, as a typical example of setting, it is assumed that a sum of the channel widths of the MOS transistors in the OFF state to generate a leak current in the memory cell array is set to about 2.8 [μm]. In this case, the value of sum of the memory mat as a whole can be obtained as 2.8×512×1024 1468006 [μm].

A leak current of the memory array becomes 2.5E-7[A] because a leak current under the gate voltage of 0V of the MOS transistor having the thick gate is 1.7E-13 [A/μm] per unit channel width from FIG. 4.

Since the peripheral circuit is formed of a MOSFET having the thin gate, a leak current becomes 1.9E-5[A] using a sum of the channel widths of the peripheral circuits of the calculation example. For the memory module as a whole, a sum of the leak current becomes equal to the value explained above, namely 1.9E-5[A] which is a value almost determined by the leak current of the peripheral circuits.

(c) Meanwhile, a total sum of the channel widths of the peripheral circuits when the peripheral circuits are also formed of the MOS transistors having the thick gates becomes 293601 [μm] (=1468006×0.2). In this case, a leak current of the memory module as a whole becomes 3.0E-7 [A].

When a leak current under the waiting condition allowed for the semiconductor integrated circuit is assumed as 1E-6[A] at the room temperature by taking a battery power supply or the like into consideration, the values in the items (a) and (b) is larger than the allowable value. Since a gate/tunnel leak current of the MOS transistor having the thin gate is ignored in the calculations in the items (a) and (b), a leak current further increases more than the above calculation value when the gate/tunnel leak is considered. As will be understood from above calculation, when the gate thickness becomes about 3 μm], a leak current becomes large which cannot be ignored even when the peripheral circuits other than the memory cell array are formed of the MOS transistors having thin gate.

From above explanation, it can be understood that it is effective for appropriate reduction of a leak current during the waiting condition of the semiconductor integrated circuit that the memory module as a whole is formed of the MOS transistor having the thick gate like the first gate insulation film 28.

In the circuit structure of FIG. 8, a substrate bias voltage is not applied to the MOS transistor. Namely, the substrate gate of the N-channel MOS transistors N1, N2 is set to the reference potential of the circuit or to the ground potential Vss with the connection illustrated in the figure, while the substrate gate of the P-channel MOS transistor is set to the power source voltage Vdd of the circuit.

The substrate bias impression technique results in the merit or demerit as explained above. Therefore, considering above explanation, the substrate bias is not employed in the semiconductor integrated circuit of FIG. 1.

The semiconductor integrated circuit of the embodiment introduces a multilayer wiring structure like the ordinary semiconductor integrated circuit device.

The multilayer wiring introduces a five-layer wiring structure, although not particularly restricted. It is a matter of course that the multilayer wiring structure is formed with the well known technique in which formation of insulation film to the semiconductor substrate on which MOS transistors are formed, formation of an adequate aperture to the insulation film, formation of a metal layer as a conductive layer, formation of the conductive layer with the photolithography, formation of an interlayer insulation film, formation of an aperture and formation of a conductive layer are repeated.

The first and second wiring layers counted from the semiconductor substrate side are formed for connections within the blocks, while the third to fifth wiring layers are formed for signal wirings between blocks and for power supply wirings. Such third and fifth wiring layers are also used as wirings in the block as required in some cases.

In this embodiment, a structure of the power supply ring wiring as explained above is adapted to respective blocks. The power supply ring wiring is formed to substantially surround the corresponding blocks. This power supply ring wiring results in the merit that the power supply wiring can be set easily in the comparatively short distance to the desired circuit within the block. It is desirable to implement adequate feeding of power source to the desired circuit in the block that the power supply ring wiring is made in the shape of the closed ring but the shape of ring which is partly opened may also be understood to substantially form the ring.

The power supply ring wiring is recommended, although not particularly restricted, to be formed of the first and second wiring layers. Power feeding to the circuits in the block can be implemented by comparatively lower wiring layers by forming the power supply ring wiring by comparatively lower wiring layers. In other words, wires may be laid effectively. In this case, power feeding to the power supply ring wiring is conducted via a wiring layer upper than the power supply ring wiring.

As explained above, this power supply ring wiring structure for each block makes easier the power feeding to the block and the control of power source voltage feeding in unit of the block. The suitable power supply ring wiring introduces the structure that not only one wiring of a pair of wirings but also a pair of wirings required for power source feeding are extended in the shape of flat ring.

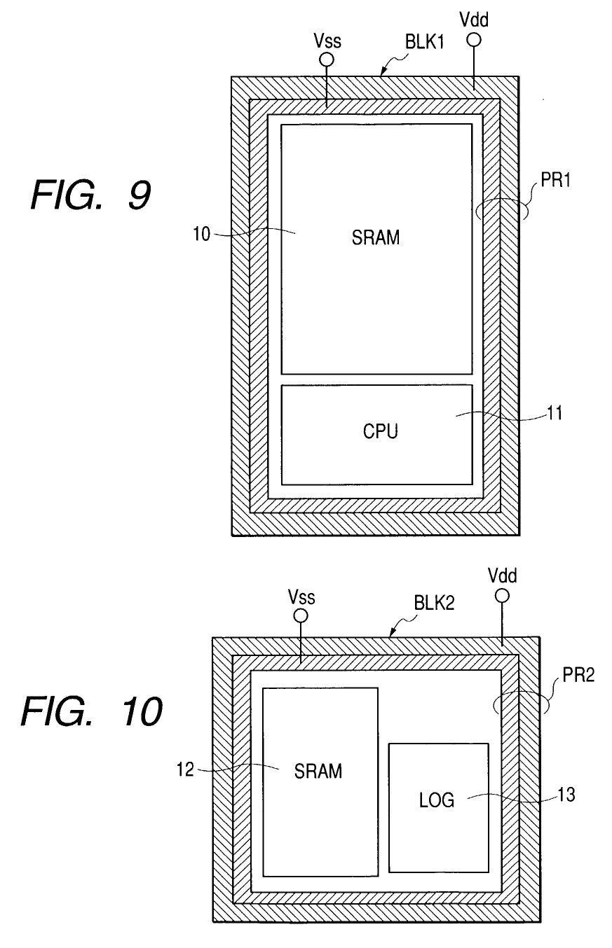

Structures of the power supply ring PR1 to PR4 of each block are illustrated in FIG. 9 to FIG. 12.

In FIG. 9 and FIG. 10, the first power source (Vdd) is supplied to the first block BLK1 and the second block BLK2. The power supply rings PR1, PR2 are formed of the ring of the first power source Vdd and the ring of the ground potential Vss. The power supply wirings to feed the power source to the SRAM10, CPU 11, SRAM 12 and internal circuit of the logic circuit LOG are omitted here.

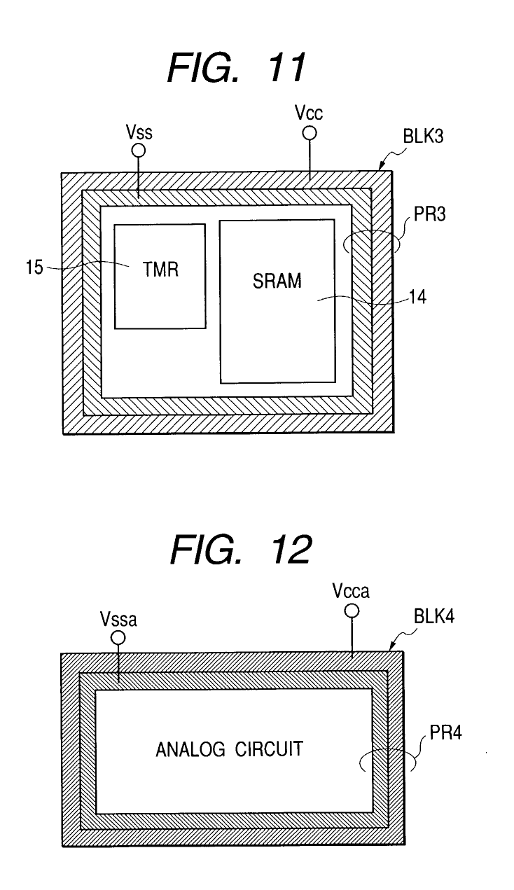

In FIG. 11, the second power source (Vcc) is supplied to the third block BLK3. The power supply ring PR3 is formed of the ring of the second power source Vcc and the ring of the ground potential Vss. The power supply wirings to feed the power source to the SRAM14 and internal circuit of TMR15 are also omitted here.

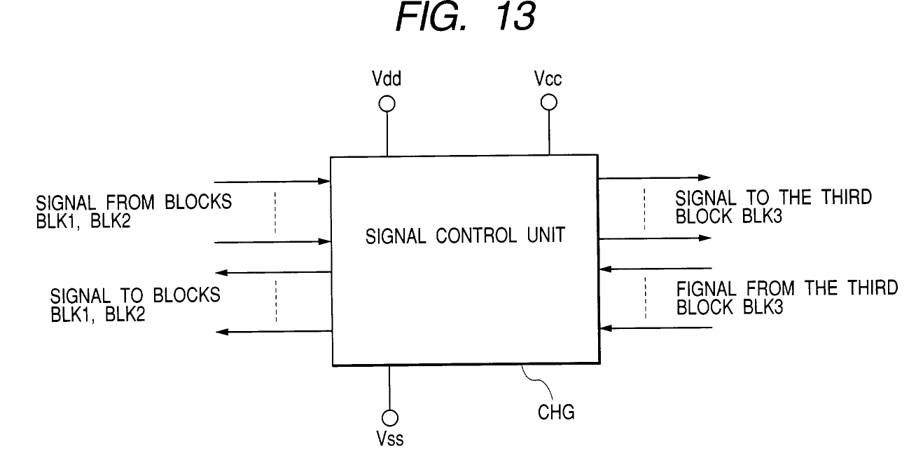

In FIG. 12, the third power source (Vcca) is supplied to the fourth block BLK4. The power supply PR4 is formed of the ring of the third power source Vcca and the ring of the ground potential of the circuit Vssa. The power supply wirings to feed the power sources to the internal circuits of the analog circuit are omitted here. The third power source voltage (Vcca) is identical to the second power source voltage (Vcc) but a certain change of layout, for example, use of different bonding pads, is considered to prevent the leak of noise generated in the digital circuit to the analog circuit. Similarly, noise resistance can also be improved by introducing the analog ground potential Vssa from the other exclusive power supply pad which is different from that used for the ground potential Vss.

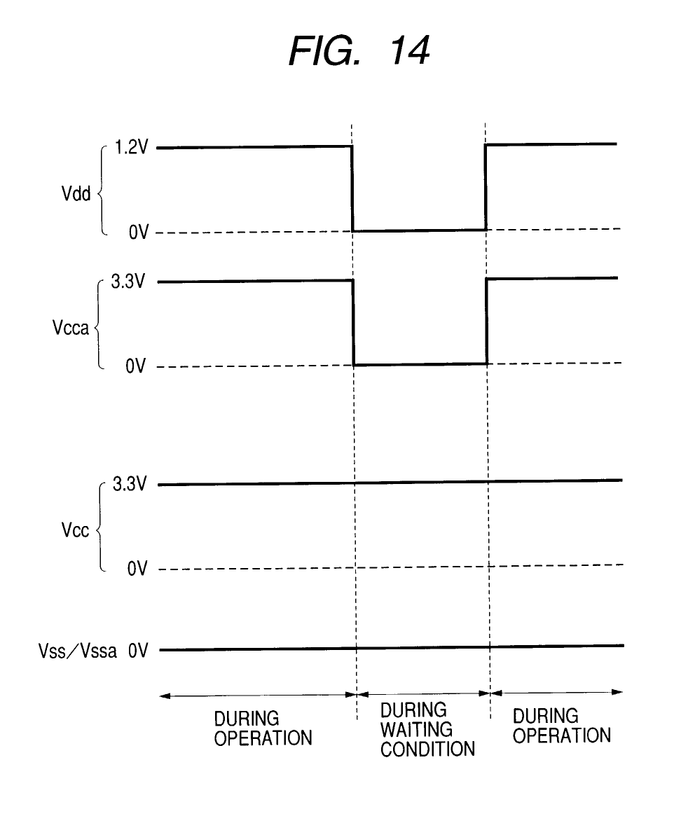

FIG. 13 illustrates a signal control unit CHG. To this signal control unit CHG, the first power source (Vdd) and the second power source (Vcc) are supplied. During the normal operation, the signal control unit executes the level conversion to the signal of Vcc system from the signal of Vdd system supplied to the third block BLK3 from the first block BLK1 and second block BLK2. Moreover, on the contrary, this unit executes the level conversion to the signal of Vdd system from the signal of Vcc system to be supplied to the first block BLK1 or the second block BLK2 from the third block BLK3. When the first power source Vdd is cut off, the signals from the first block BLK1 and the second block BLK2 become uncertain and in this timing, the first power source Vdd to the signal control unit CHG is also cut off. The signal control unit CHG senses such cut-off condition of power source and forcibly sets the signal line to the third block from the first block BLK1 and second block BLK2, for example, to the ground level Vss in order to control the input of uncertain signal to the third circuit block BLK3.

FIG. 14 illustrates the power feeding conditions in the operating condition and the waiting condition of the semiconductor integrated circuit. During the waiting condition, the power sources other than the second power source (Vcc) is cut off in the external circuits.

In the third block BLK3, the circuits which must be operated even during the waiting condition, for example, the SRAM14 which is required to hold the control data even during the waiting condition of the semiconductor integrated circuit and the timer 15 for executing recovery from the waiting condition and the waiting operation are formed. The gate insulation film of the MOS transistor forming this third block BLK3 is formed to be thicker than that of the MOS transistors of the first block BLK1 and the second block BLK2 in which the circuits not operated in the waiting condition are formed. Therefore, the sub-threshold leak current of the third block BLK3 which is operated even in the waiting condition and the tunnel leak current of the gate electrode can be reduced. For example, when film thickness of the MOS transistor forming the third block BLK3 is 8 nm, while film thickness of the MOS transistors forming the first block BLK1 and the second block BLK2 is 3 nm, the sub-threshold leak current can be reduced by about three digits in comparison of transistors and the tunnel leak current of the gate electrode can be reduced to almost zero. The sub-threshold leak current can be reduced, the tunnel leak current of the gate electrode can be reduced, a leak current can be reduced to the negligible level even when the memory or the like is set to the waiting condition for the data holding purpose and thereby life-span of the battery can be extended when the present semiconductor integrated circuit is applied to the battery power supply system.

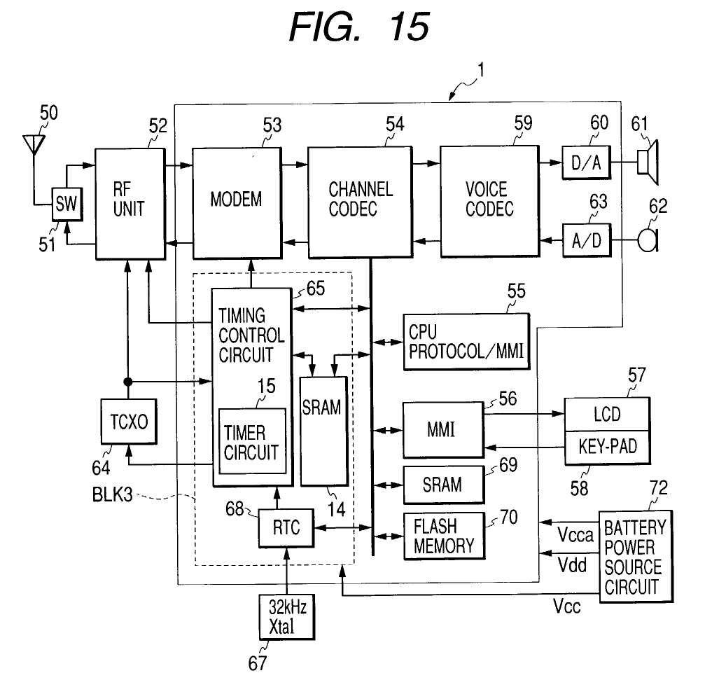

FIG. 15 illustrates a mobile phone as an example of the data processing system to which the semiconductor integrated circuit of the present invention is adapted.

A receiving signal of the radio bandwidth received by an antenna 50 is transmitted to a radio frequency (RF) unit 52 as a receiving signal via an antenna switch 51. The receiving signal is converted by the RF unit 52 into a low frequency signal and is then inputted to a modem 53. The receiving signal is demodulated in the modem 53 and is then converted to a digital signal as an input signal to a channel codec 54. The channel codec 54 cancels secrecy of the received digital signal and then executes error correction and detection in order to sort the signal to the communication data such as control data and compressed audio data which are required to implement communication.

The control data is sent to the CPU 55 and is subjected to the communication protocol process therein. Moreover, the CPU 55 drives a liquid crystal display 57 via the MMI (Man-Machine Interface) unit 56 and also executes the man-machine interface function to process the key-depression information sent from a key-pad 58 via the man-machine interface unit 56.

Moreover, the audio data extracted in the channel codec 54 is expanded in a voice codec 59, subjected to digital analog conversion and filter process as audio data in the D/A unit 60 and is then reproduced as an voice information from a speaker 61.

In the transmitting operation, the audio signal inputted from a microphone 62 is subjected to the filter process and analog-to-digital conversion in the A/D unit 63 and is then inputted to a voice codec 69. The voice codec 69 compresses the audio data and converts this data to the compressed audio data. The channel codec 54 generates a transmitting data train by combining the compressed audio data of the voice codec 59 and the control data from the CPU 55 and adds an error correction/detection code and secrecy code to this data train and thereafter outputs the transmitting data to the modem 53. The transmitting data is converted to a modulated signal from the digital signal in the modem 53. Thereafter, the modulated signal is then converted in the RF unit 52 to the RF signal in the radio signal bandwidth and is amplified. This amplified signal is then transmitted as a radio signal from the antenna 50 via the antenna switch 51. The channel codec 54 and voice codec 59 are formed of an exclusive logic circuits or of a DSP (Digital Signal Processor) or the like.

In this FIG. 15, the reference numeral 64 designates a TCXO (temperature compensation type voltage-controlled oscillator) and a clock signal generated therein is supplied as a reference clock signal of the RF unit 52 and moreover a timing control circuit 65 which generates the timing signal required by a mobile phone to perform communication. The timing control circuit 65 supplies the operation clock signal to the modem 53 and CPU 55 in order to control the operations of the RF unit 52. The mobile phone is usually in the communication mode for conducting communication and waiting mode for waiting origination of a call by a user and termination of a call from the mobile communication network. The mobile phone establishes the frame synchronization to make communication with a base station and determines the receiving location and transmitting location. Even in the waiting mode, the mobile phone periodically receives the radio signal transmitting periodically from the base station. This is called an intermittent reception mode. In order to predict the location of signal which is periodically transmitted from the base station, frame synchronization must be established. Here, an oscillator 67 for timer is used to maintain the frame synchronization in the period where the signal is not received in the intermittent reception mode. The clock of the oscillator 67 for timer is supplied to the RTC (Real Time Clock) unit 68 for timer and is also supplied to the timing control circuit 65 simultaneously. In the period where the receiving operation is not conducted in the intermittent reception mode, the timing control circuit 65 maintains the frame synchronization based on the output clock signal of the RTC 68 and cuts off the power supply of TCX 64. The timing control circuit 65 also generates the power supply ON timing of the TCXO 64 at the predetermined position from the receiving location in the intermittent reception mode. Numeral 70 designates a flash memory to store the operation program of CPU 55, and 69 is an SRAM to be used as a work region or the like of the CPU 55.

In FIG. 15, the timing control circuit 65, SRAM 15, RTC 68 are structured by the third block BLK3. The D/A60, A/D63 are structured by the fourth block BLK4. CPU 55, MMI 56, SRAM 69 and flash memory 70 are structured by the first block BLK1. The modem 53, channel codec 54 and voice codec 59 are structured by the second block BLK2. The semiconductor integrated circuit illustrated in FIG. 15 operates with the external power sources of Vdd, Vcc, Vcca supplied from the battery power supply circuit 72.

The semiconductor integrated circuit 1A illustrated in FIG. 15 is identical to FIG. 1 in its basic structure but the control for supply and stop of the operation power source for the first block BLK1, second block BLK2 and fourth block BLK4 are performed by the timing control circuit 65 of the third block 3. For example, the timing control circuit 65 impresses, under the waiting condition, the external operation power source Vdd to the first block BLK1 and second block BLK2 in every period to turn ON the power supply of the TCXO 64 at the predetermined position from the receiving location of the intermittent operation mode and also supplies the external operation power source Vcca to the fourth block BLK4 and stops impression, in the other period, of the power sources Vdd, Vcca to the corresponding circuits. For this control for impression and stop of impression of the power source, a switch not illustrated is provided between the power supply pad 2a and power supply rings PR1, PR2 and between the power supply pad 2d and power supply ring PR4 illustrated in FIG. 1.

According to the above explanation, power consumption in the waiting condition of a mobile phone can be reduced and life-span of a battery in the battery power supply circuit 72 can be extended.

The present invention has been explained practically based on the embodiments thereof but the present invention is not limited thereto and allows various changes and modifications within the scope not departing from the claims thereof.

For example, the MO transistor having the thick second gate may be formed of the MO transistor having the gate in the same thickness as an element forming the I/O block, but when importance is placed on the performance of the memory and the other circuits, if a leak current in the waiting condition is equal to the value satisfying the requested specifications of the system LSI or less, the MO having the third gate which is thicker than the first gate but is thinner than the second gate may be used. In this case, optimization can be attained by lowering the power supply voltage than the second power source voltage.

The memory for holding data and the circuit such as timer may be formed of the MOS transistor having the second gate thickness and the MOS transistor having the third gate thickness. In this case, it is required to supply two kinds of power source voltages as a power supply ring.

As an example of the memory which requires holding of data, the static RAM utilizing the CMOS static latch type memory cell formed of six MOSFETs is employed but the present invention is not limited to this memory and can use, as a load, the static RAM of the memory cell using the resistor having high resistance value or the multi-port RAM such as dual-port RAM.

In the present invention, cut-off control of the power sources Vcca and Vdd may also be implemented through the control by an external circuit of the semiconductor integrated circuit or by the internal control with the power supply control circuit within the chip.

The practical circuit structure of the digital circuit included in the semiconductor integrated circuit and the other on-chip circuit module are not limited to above explanation and may be changed or modified as required.

Application of the present invention into a mobile phone which is the major application field as a background of the present invention has been explained above but the present invention is not limited thereto. For example, the present invention can also be applied widely to the system such as a car navigation system which requires to reduce the power consumption in the waiting condition as much as possible or to the apparatus such as FAX or terminal adaptor which required to hold the data with the battery during the power failure.

The major effects of the present invention will be briefly explained.

Namely, since the gate insulation film of the MOS transistor forming the first digital circuit in which a circuit which is required to be operated by a battery even under the waiting and power failure condition is formed to be thicker than the MOS transistor of the second digital circuit in which a circuit which is not required to be operated during the waiting condition is formed, the sub-threshold leak current of the first digital circuit which is also operated in the waiting condition and the tunnel leak current of the gate electrode can be reduced. Therefore, when the present invention is applied to the battery power supply system, the life-span of the battery can also be extended.

In the case where the MOS transistor forming the first digital circuit is formed with inclusion of the gate insulation film in the same thickness as a MOS transistor forming the interface circuit, addition of a new process is unnecessary if the gate film thickness of the MOS transistor of the first digital circuit is different from the MOS transistor of the second digital circuit.

When the gate film thickness of the first digital circuit is unified to single value, the operation power sources of the first digital circuit can also be unified to single power source value without addition of the power supply of a new power source level.

What is claimed is:

1. A semiconductor integrated circuit formed on a semiconductor substrate comprising:
an external terminal;
an interface circuit connected to said external terminal;
a first digital circuit including a first memory with a memory cell array and a peripheral circuit thereof; and
a second digital circuit including a logic circuit,
wherein a gate insulation film of MOS transistors forming said first digital circuit is formed to be thicker than a gate insulation film of MOS transistors forming said second digital circuit.

2. A semiconductor integrated circuit according to claim 1, wherein the first memory of said first digital circuit is operated even during the waiting condition, while the logic circuit of said second digital circuit is not operated during, the waiting condition.

3. A semiconductor integrated circuit according to claim 1 or 2, wherein said first memory is an SRAM and said first digital circuit further comprises a first logic circuit.

4. A semiconductor integrated circuit according to claim 3, wherein said first logic circuit is a timer circuit.

5. A semiconductor integrated circuit according to claim 3, wherein said second digital circuit further comprises a second memory and a second logic circuit.

6. A semiconductor integrated circuit according to claim 1, wherein a MOS transistor forming said first digital circuit includes the gate insulation film in the same thickness as the MOS transistor forming said interface circuit.

7. A semiconductor integrated circuit according to claim 1, wherein the MOS transistor forming said first digital circuit has the gate insulation film thinner than the gate insulation film of the MOS transistor forming said interface circuit.

8. A semiconductor integrated circuit according to claim 1, wherein a part of MOS transistors forming said first digital circuit includes the gate insulation film in the same thickness as the MOS transistors forming said interface circuit, while the remaining MOS transistors include the gate insulation film thinner than the above gate insulation film.

9. A semiconductor integrated circuit according to claim 6 or 7, wherein an operation power source of said first digital circuit is single power supply.

10. A semiconductor integrated circuit according to claim 1 or 2, wherein an operation power source supply route of said first digital circuit is formed separately from an operation power source supply route of said second digital circuit.

11. A semiconductor integrated circuit according to claim 10, wherein the operation power source supply route of said first digital circuit is a power supply ring laid at the external side of said first digital circuit.

12. A semiconductor integrated circuit according to claim 10, including an exclusive external power supply terminal only for input of operation power source of said first digital circuit.
